(19) United States
(12) Patent Application Publication
(10) Pub. No.: US 2004/0175909 A1
(43) Pub. Date: Sep. 9, 2004

(54) Semiconductor device and method for fabricating the same

(75) Inventor: Michikazu Matsumoto, Kyoto (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/791,777

(22) Filed: Mar. 4, 2004

(30) Foreign Application Priority Data
Mar. 5, 2003 (JP) 2003-058804

(51) Int. Cl. H01L 21/336; H01L 21/3205; H01L 21/4763; H01L 21/8234

(52) U.S. Cl. 438/592; 438/587; 438/279; 438/275; 438/197

(57) ABSTRACT

In a semiconductor device including a MOS transistor with a gate electrode, a dummy pattern is spaced away from both sides of the gate electrode, a first silicide layer is formed in the upper portion of the gate electrode, a second silicide layer is formed in a region between the gate electrode and the dummy pattern, and the first silicide layer has a greater thickness than the second silicide layer.

### BACKGROUND OF THE INVENTION

(1) Field of the Invention

The present invention relates to semiconductor devices and methods for fabricating the same. In particular, the present invention relates to semiconductor devices including MOS transistors and methods for fabricating the same.

(2) Description of the Related Art

Recently, in order to still further enhance the speed and the integrated density of LSIs including MOS transistors, strong demands for miniaturization of the MOS transistors have increasingly grown.

To develop miniaturization of the MOS transistor, not only must the gate length and the gate width of the transistor be reduced, but the junction depth of the source/drain diffusion layer thereof must also be reduced. In addition, for the purpose of the miniaturization, the source/drain diffusion layer is formed with a lightly doped drain (LDD) structure (for example, Japanese Unexamined Patent Publication No. 2002-190589).

However, the reduction in the gate length causes an increase in the sheet resistance of the gate electrode, and the shrinkage and the shallow junction formation of the source/drain diffusion layer cause an increase in the sheet resistance of the diffusion layer. Therefore, the increases in these resistances should also be compensated.

To deal with the increases in these resistances, in recent years, salicide process has been widely used in which the upper portion of the gate electrode and the surface of the source/drain diffusion layer are formed with silicide layers of low resistance. The salicide process provides low-resistance layers in the following manner. First, using sputtering technique, metal of high melting point (for example, cobalt (Co), titanium (Ti), or nickel (Ni)) is deposited over the top of the gate electrode formed of polysilicon and on a silicon surface portion of a substrate serving as the source/diffusion layer. Subsequently, heat treatment is conducted to allow the reaction of the high melting point metal film with polysilicon in the upper portion of the gate electrode and with silicon in the surface of the source/drain diffusion layer, thereby forming silicide layers.

### SUMMARY OF THE INVENTION

In LSIs including MOS transistors, there exists a region in which a plurality of gate electrodes are adjacently arranged in array form. When high melting point metal is deposited on this region, the metal film deposited on the surface of a source/drain diffusion layer which is interposed between two gate electrodes has a smaller thickness than the metal film deposited on the surface of a source/drain diffusion layer which is located next to an edge of the gate electrode array and of which only one side adjoins the gate electrode. This phenomenon results from poor step coverage of the film formed by sputtering technique. Consequently, the silicide layers on the surfaces of the source and drain diffusion layers also differ in thickness depending upon whether the individual silicide layers are interposed between two gate electrodes or not interposed.

If the silicide layers on the surfaces of the source and drain diffusion layers differ in thickness as mentioned above, the following problem arises.

For a region with a thick silicide layer, the diffusion depth of the source/drain diffusion layer cannot be made shallower. If the diffusion layer in this region is forcibly formed with a shallow junction, a very large junction leakage current flows, resulting in degradation in characteristics of the device. On the other hand, for a region with a thin silicide layer, the sheet resistance thereof is not sufficiently reduced. If the silicide layer is too thin, the possibility of disconnection or other trouble in the device increases.

In order to decrease the difference in thickness between the silicide layers on the surfaces of the source and drain diffusion layers, it is sufficient to reduce the heights of the gate electrodes. However, it is becoming very difficult to reduce the heights of the gate electrodes, that is, to reduce the thicknesses of the polysilicon films constituting the electrodes with the transistor characteristics kept. If the polysilicon film is thinned, ion implantation in forming source and drain electrodes causes channeling of ions along grain boundaries. Then, the ions are unstably implanted under the gate electrode, so that leakage current flowing between the source and drain of the transistor increases. Accordingly, it is impractical to simply reduce the thickness of the polysilicon film.

Aiming to solve the above problem, collimated sputtering is proposed as the sputtering technique for allowing materials of the high melting point metal film to have a higher directivity during the film deposition. If the high melting point metal film is formed using the collimated sputtering technique, the thickness difference between the region with the thin film and the region with the thick film like the above-mentioned conventional example is reduced. Therefore, this technique can be employed as one of approaches for solving the problem.

However, simple reduction in the thickness difference between the region with the thin film and the region with the thick film cannot meet the miniaturization of today's semiconductor device. Specifically, in the case where the gate length thereof is 0.15 μm or smaller, the gate length and the gate width become so small that it is difficult to form a silicide film on the gate electrode. If the silicide formation process is insufficiently conducted, disconnection easily occurs in the device, which is a major cause of a decrease in the device yield. Hence, the target for formation of silicide films in future miniaturization process is that the silicide film on the gate electrode is formed to be as thick as possible while the silicide film on the source/drain diffusion layer is formed to be thin (which results in a shallow junction depth).

The present invention has been made in view of said fact, and its object is to provide a semiconductor device which has suicide layers of a uniform thickness on source and drain diffusion layers and a disconnection-free, thick silicide layer on a gate electrode, and to provide a fabrication method of the device.

A first semiconductor device of the present invention comprises a MOS transistor with a gate electrode. A dummy pattern is spaced away from both sides of the gate electrode. A first silicide layer is formed in the upper portion of the gate electrode. A second silicide layer is formed in a region between the gate electrode and the dummy pattern. The first silicide layer has a greater thickness than the second silicide layer.

A second semiconductor device of the present invention comprises a MOS transistor with a plurality of gate electrodes. Each of the gate electrodes is arranged between the other gate electrodes or between one of the gate electrodes and a dummy pattern with a space left from each side thereof. A first silicide layer is formed in the upper portion of the gate electrode. A second silicide layer is formed in a region between the gate electrode and at least one of another gate electrode and the dummy pattern. The first silicide layer has a greater thickness than the second silicide layer.

In one embodiment, the dummy pattern is a dummy gate electrode which is an electrode pattern having the shape of a gate electrode, and the dummy pattern is an electrode which is not electrically connected to a semiconductor integrated circuit of the semiconductor device.

In one embodiment, the dummy pattern is made of insulating material.

In one embodiment, the dummy pattern is either a pattern made of insulating material or a dummy gate electrode which is an electrode pattern having the shape of a gate electrode and is not electrically connected to a semiconductor integrated circuit of the semiconductor device.

In one preferred embodiment, the MOS transistor is formed in an element region surround with an isolation insulating film, and the pattern made of insulating material is formed on the isolation insulating film.

Preferably, the thickness of the second silicide layer is 80% or less of the thickness of the first silicide layer.

Preferably, the MOS transistor is formed in an element region surrounded with an isolation insulating film, and the thickness of the second silicide layer or layers satisfies 2(TM−Tm)/(TM+Tm)<0.3, where TM and Tm are the maximum and minimum thickness of the second silicide layer or layers in the element region, respectively.

Preferably, the distance A from a side wall of the gate electrode to a side wall of another said gate electrode or a side wall of the dummy pattern adjacent to the gate electrode holds the relation: A≦2B relative to the height B of the gate electrode.

In one preferred embodiment, the MOS transistor is formed in an element region surrounded with an isolation insulating film. The gate electrode comprises two portions extending substantially parallel to each other and a connecting portion connecting respective ends of the two portions to each other. The connecting portion is located on the isolation insulating film, and the distance C from the boundary between the isolation insulating film and the element region to the connecting portion holds the relation: C≧2B relative to the gate electrode height B.

Preferably, the MOS transistor has a gate length of 0.15 μm or smaller.

Preferably, the first and second silicide layers contain one selected from the group consisting of CoSiₓ, TiSiₓ, NiSiₓ, and PtSiₓ, and x satisfies 0<x≦2.

A third semiconductor device of the present invention comprises a MOS transistor with a plurality of gate electrodes. The gate electrodes are formed on a semiconductor substrate having a silicon layer at least in the surface thereof The MOS transistor has a gate length of 0.15 μm or smaller and is formed in an element region surrounded with an isolation insulating film. Each of the gate electrodes is arranged between the other gate electrodes or between one of the other gate electrodes and a dummy pattern with a space left from each side thereof Sidewalls are provided on side walls of each of the gate electrodes and on side walls of another said gate electrode. A first silicide layer is formed in the upper portion of the gate electrode. A second suicide layer is formed in a portion of the semiconductor substrate surface which is located in part of the element region between the gate electrode and at least one of another gate electrode and the dummy pattern. The first silicide layer has a greater thickness than the second silicide layer.

In one embodiment, the dummy pattern is a dummy gate electrode which is an electrode pattern having the shape of a gate electrode, side walls of the dummy pattern are provided with sidewalls, and the dummy pattern is an electrode which is not electrically connected to a semiconductor integrated circuit of the semiconductor device.

In one embodiment, the dummy pattern is made of insulating material.

In one embodiment, the dummy pattern is either a pattern made of insulating material or a dummy gate electrode which is an electrode pattern having the shape of a gate electrode with side walls of the dummy pattern provided with sidewalls and is not electrically connected to a semiconductor integrated circuit of the semiconductor device.

In one preferred embodiment, the pattern made of insulating material is formed on the isolation insulating film.

A first method for fabricating a semiconductor device of the present invention comprises the steps of: forming a gate insulating film on a semiconductor substrate having a silicon layer at least in the surface thereof, and depositing an amorphous silicon film or a polysilicon film on the gate insulating film; patterning the amorphous silicon film or the polysilicon film to form a gate electrode and at least one of another gate electrode and a dummy gate electrode, at least one said electrode being spaced away from both sides of the gate electrode; doping impurities into the semiconductor substrate to form doped layers serving as a source and a drain; and depositing a metal film on the semiconductor substrate, the gate electrode, and another said gate electrode or the dummy gate electrode, and performing heat treatment on the metal film, thereby forming silicide on the semiconductor substrate, the gate electrode, and at least one electrode of another said gate electrode and the dummy gate electrode.

Preferably, the first method further comprises the step of forming sidewalls on side walls of the gate electrode and on side walls of at least one electrode of another said gate electrode and the dummy gate electrode.

A second method for fabricating a semiconductor device of the present invention comprises: the step of forming a gate insulating film on a semiconductor substrate having a silicon layer at least in the surface thereof, and depositing an amorphous silicon film or a polysilicon film on the gate insulating film; the step of patterning the amorphous silicon film or the polysilicon film to form a plurality of aligned gate electrodes in array form; the step A of doping impurities into the semiconductor substrate to form doped layers serving as a source and a drain; the step B of depositing an insulating layer on the semiconductor substrate; the step C of patterning the insulating layer to form dummy patterns disposed away from both sides of the electrode array in the alignment direction thereof, respectively; and the step of depositing a metal film on the semiconductor substrate, the gate electrode, and the dummy patterns, and performing heat treatment on the metal film, thereby forming silicide on the semiconductor substrate and the gate electrode. The step A may be performed either before or after the steps B and C.

A third method for fabricating a semiconductor device of the present invention comprises the steps of: forming an isolation insulating film on a semiconductor substrate having a silicon layer at least in the surface thereof to form an element region surrounded with the isolation insulating film; forming a gate insulating film on the semiconductor substrate, and depositing an amorphous silicon film or a polysilicon film on the gate insulating film; patterning the amorphous silicon film or the polysilicon film to form a gate electrode on the element region and form a dummy gate electrode disposed on the isolation insulating film and adjacent to the gate electrode; doping impurities into the semiconductor substrate to form doped layers serving as a source and a drain; depositing an insulating layer on the semiconductor substrate; patterning the insulating layer to form a dummy pattern disposed on the isolation insulating film and adjacent to the gate electrode; and depositing a metal film on the semiconductor substrate, the gate electrode, the dummy gate electrode, and the dummy pattern, and performing heat treatment on the metal film, thereby forming silicide on the semiconductor substrate, the gate electrode, and the dummy gate electrode.

Preferably, the third method further comprises the step of forming sidewalls on side walls of the gate electrode and on side walls of the dummy gate electrode.

Preferably, the metal film contains one selected from the group consisting of Co, Ti, Ni, and Pt.

### BRIEF DESCRIPTION OF THE DRAWINGS

FIG. 1A is a schematic plan view of a semiconductor device according to a first embodiment of the present invention, and FIG. 1B is a schematic sectional view taken along the line X-X′ of FIG. 1A.

FIGS. 2A-2E are cross-sectional views schematically showing process steps of fabricating a semiconductor device according to the first embodiment.

FIG. 3 is a schematic plan view of a semiconductor device according to a second embodiment of the present invention.

FIG. 4A is a schematic plan view of a semiconductor device according to a third embodiment of the present invention, and FIG. 4B is a schematic sectional view taken along the line X-X′ of FIG. 4A.

FIG. 5A is a schematic plan view of a semiconductor device according to a fourth embodiment of the present invention, and FIG. 5B is a schematic sectional view taken along the line X-X′ of FIG. 5A.

FIG. 6A is a schematic plan view of a semiconductor device according to a comparative example, FIG. 6B is a schematic sectional view taken along the line X-X′ of FIG. 6A, and FIG. 6C is a schematic sectional view taken along the line Y-Y′ of FIG. 6A.

FIG. 7A is a schematic plan view showing a gate electrode portion of a semiconductor integrated circuit according to the first embodiment of the present invention, and FIG. 7B is a schematic sectional view taken along the line Z-Z′ of FIG. 7A.

FIG. 8A is a schematic plan view of a semiconductor device according to a fifth embodiment of the present invention, and FIG. 8B is a schematic sectional view taken along the line A-A of FIG. 8A.

FIGS. 9A-9F are cross-sectional views schematically showing process steps of fabricating a semiconductor device according to the fifth embodiment.

FIG. 10A is a schematic plan view of a semiconductor device according to a sixth embodiment of the present invention, and FIG. 10B is a schematic sectional view taken along the line A-A of FIG. 10A.

FIGS. 11A-11F are cross-sectional views schematically showing process steps of fabricating a semiconductor device according to the sixth embodiment.

FIG. 12A is a schematic plan view of a semiconductor device according to a seventh embodiment of the present invention, and FIG. 12B is a schematic sectional view taken along the line A-A of FIG. 12A.

### DETAILED DESCRIPTION OF THE PREFERRED EMBODIMENTS

Hereinafter, embodiments of the present invention will be described in detail with reference to the accompanying drawings.

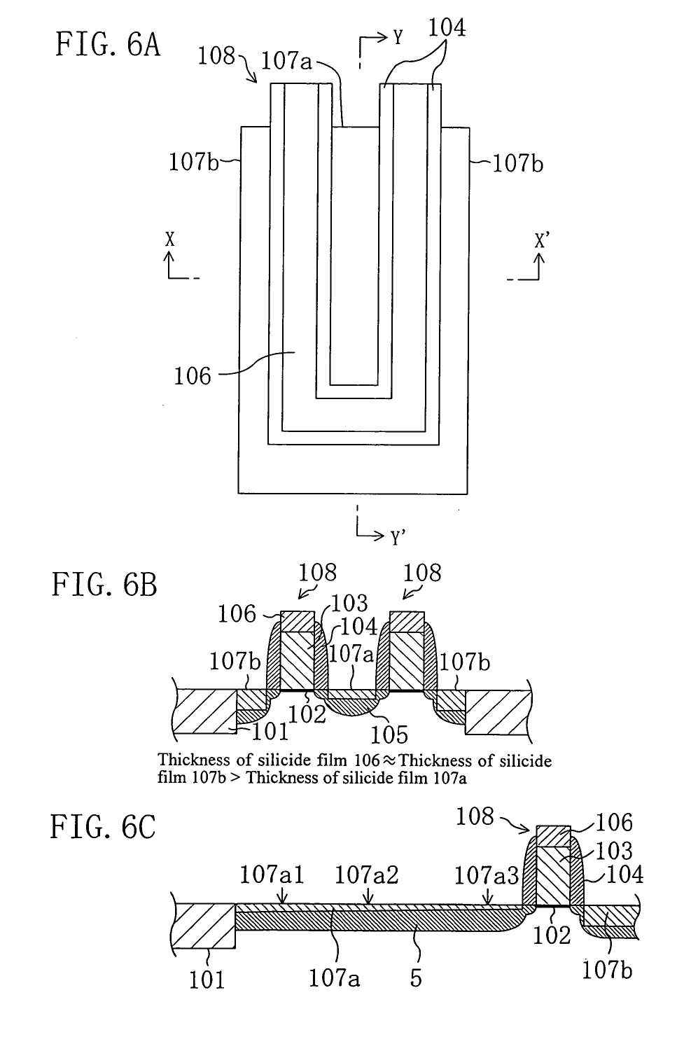

Prior to the description of each embodiment of the present invention, as a comparative example, a semiconductor device to which the present invention is not applied will be illustrated using FIG. 6. FIG. 6A is a plan view, FIG. 6B is a sectional view taken along the line X-X′, and FIG. 6C is a sectional view taken along the line Y-Y′.

Referring to the semiconductor device as the comparative example shown in FIG. 6, a gate electrode 108 bent in U-shape is formed in an element region (a region in which the gate electrode 108 and a source/drain diffusion layer 105 are formed) surrounded with an isolation insulating film 101.

In FIG. 6, the isolation insulating film 101 serves to electrically isolate transistors from each other. The reference numeral 102 denotes a gate insulating film of the transistor. The reference numeral 103 denotes a polysilicon film forming the gate electrode 108. The gate electrode 108 may be formed of an amorphous silicon film instead of the polysilicon film. The reference numeral 104 denotes a side wall of an insulating film which is formed subsequently to lightly doped drain (LDD) implantation, extension (EX) implantation, pocket implantation, or other implantation. The reference numeral 105 denotes the source/drain diffusion layer which is formed by implanting ions at high concentration and then performing heat treatment. The reference numeral 106 denotes a silicide film which is formed on polysilicon serving as the gate electrode 108. The reference numeral 107a denotes a silicide film which is formed on the source/drain diffusion layer 105. The reference numeral 107b also denotes a silicide film which is formed on the source/drain diffusion layer 105.

The silicide film 106 arranged on the gate electrode 108 and the silicide films 107a and 107b arranged on the source and drain diffusion layers 105 are formed as follows. A film of high melting point metal (for example, cobalt (Co), titanium (Ti), nickel (Ni), or platinum (Pt)) is deposited by sputtering technique, and then heat treatment is performed. This treatment allows the deposited film to react with the underlying polysilicon film 103 and silicon substrate portions constituting the source/drain diffusion layers 105, thereby forming silicide films.

In general, the high melting point metal film is deposited using the sputtering technique as described above. The high melting point metal film deposited by the sputtering technique, however, has poor step coverage. In other words, the high melting point metal particles to be deposited by the sputtering have poor directivity.

Moreover, the gate electrode 108 of a certain height is present in the semiconductor device shown in FIG. 6. Therefore, the high melting point metal film deposited on the region of the diffusion layer 105 surrounded with the gate electrode 108 of U-shape (the region denoted by the reference numeral 107a) has a smaller thickness than the high melting point metal film deposited on the region of the diffusion layer 105 in the lateral direction of which the gate electrode 108 other than the U-shaped electrode 108 is absent (the region denoted by the reference numeral 107b). As a result, the silicide films formed by the heat treatment subsequent to the deposition of the high melting point metal film do not have a uniform thickness, that is to say, the silicide film formed in the region 107a surrounded with the gate electrode 108 of U-shape has a smaller thickness than that formed in the region 107b not surrounded with the gate electrode 108. This phenomenon becomes more notable as the height of the gate electrode 108 is increased or the distance between the parallel sides of the gate electrode 108 is decreased. As a result, the thickness difference between the silicide films 107a and 107b becomes large.

As described above, when the thickness difference between the silicide films 107a and 107b is increased, a first problem arises from formation of a shallow junction. In order to develop miniaturization of a MOS transistor in a semiconductor device aiming at an enhanced performance of the device, not only must the gate length and the gate width of the transistor be reduced, but the junction depth of the source/drain diffusion layer 105 must also be reduced. However, in the conventional semiconductor device described above, the silicide film in the region 107b is formed to be thick, so that the diffusion layer in the region 107b cannot be formed to have a shallow depth. In this case, if the depth of the diffusion layer is forced to be shallow, junction leakage current caused by making a shallow junction of the diffusion layer 105 becomes very large. This causes the degradation in the device characteristics.

A second problem arises from the region 107a where the silicide film has a relatively small thickness. In this region, the sheet resistance thereof is not sufficiently small. In addition, if the film thickness is further reduced, the possibility of disconnection or other trouble increases.

A third problem arises from the portion denoted by the reference numeral 107a2, as shown in FIG. 6C, the three sides of which are surrounded with the gate electrode 108. Within the region 107a interposed between the parallel sides of the gate electrode 108, the silicide film is thinner at the portion 107a2. That it to say, in FIG. 6C, the silicide film thicknesses are as follows: 107a3<107a2<107a1. Accordingly, the thickness difference between the region with the thick silicide film and the region with the thin silicide film becomes wider.

In order to cope with these problems, it is considered to reduce the thickness of the high melting point metal film deposited by sputtering. In this case, the high melting point metal film deposited on the gate electrode 108 and the silicide film on the source/drain diffusion layer 105 between the parallel sides of the gate electrode 108 (the region 107a) are further reduced to very small thicknesses. As a result, it becomes more difficult to reduce the sheet resistance. Particularly for the silicide film 106 formed on the gate electrode 108, the underlying polysilicon film 103 contains grains and is heavily doped. This makes it difficult to form silicide, which may cause disconnection at this region.

In particular, at present when semiconductor devices have design rules of 0.15 μm or smaller and, for example, the gate length is as very small as 60 to 70 nm, it becomes difficult for even a high melting point metal film of a conventional thickness to form the silicide film 106 on the gate electrode 108. If the silicide formation process is insufficient, disconnection occurs easily in the device. This is a major cause to reduction in the device yield.

The inventors found that the above-mentioned problems can be solved by eliminating the thickness difference between the silicide films 107a and 107b on the source and drain diffusion layers 105. Then, as a consequence of studies, the inventors conceived the method by which the high melting point metal film deposited on any points of all the source and drain diffusion layers 105 can be formed in almost the same deposition condition, and the inventors arrived at the concept of the present invention.

Hereinafter, embodiments of the present invention will be described with reference to the accompanying drawings. In the following drawings, for simplification of description, the elements having substantially the same function bear the same reference numeral. The present invention is not limited to the following embodiments.

### First Embodiment

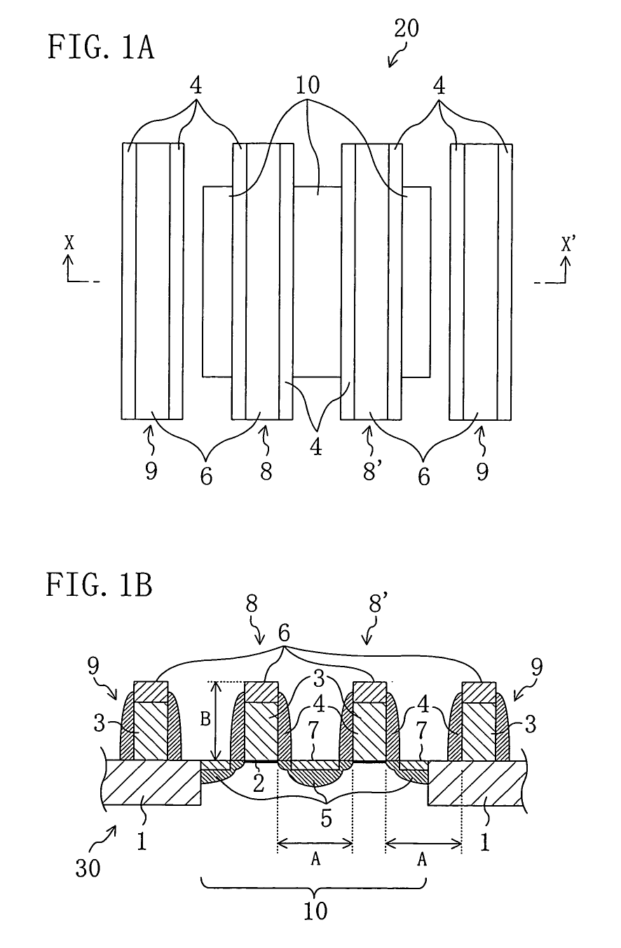

FIG. 1A is a plan view of a semiconductor device according to a first embodiment of the present invention, and FIG. 1B is a sectional view taken along the line X-X′ of FIG. 1A.

The semiconductor device of the first embodiment includes a MOS transistor 20 which is formed on an element region 10 (the region in which gate electrodes 8 and source and drain diffusion layers 5 are formed and which is also referred to as an active region) surrounded with an isolation insulating film 1. In this device, two gate electrodes 8 and 8′ are formed on a semiconductor substrate 30. Dummy gate electrodes 9 and 9 are disposed next to one side of the gate electrode 8 and one side of the gate electrode 8′, respectively. The dummy gate electrodes 9 and 9 are disposed on the isolation insulating film 1.

In the semiconductor device of the first embodiment, the isolation insulating film 1 serves to electrically isolate transistors from each other. A polysilicon film 3 constituting the gate electrode 8 is formed on the element region 10 surrounded with the isolation insulating film 1, and a polysilicon film 3 constituting the dummy gate electrode 9 is formed on the isolation insulating film 1. The reference numeral 2 denotes a gate insulating film of the transistor. The polysilicon film 3 may be an amorphous silicon film in the film deposition step. A first silicide layer 6 is formed on the polysilicon film 3. The reference numeral 4 denotes a sidewall of an insulating film which is formed subsequently to lightly doped drain (LDD) implantation, extension (EX) implantation, pocket implantation, or other implantation. In regions of the element region 10 where the gate electrodes 8 and 8′ are absent, source and drain diffusion layers 5 (doped layers) exist each of which is formed by implanting ions of high concentration and then performing heat treatment. On each of the source and drain diffusion layers 5, a second silicide layer 7 is formed.

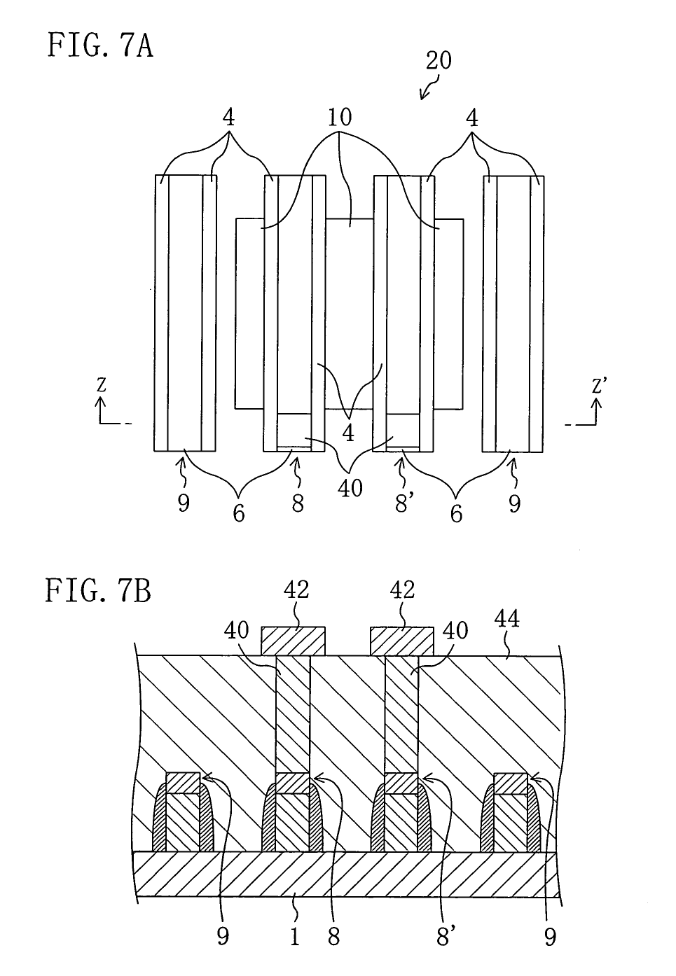

In the semiconductor device of the first embodiment, the dummy gate electrodes 9 and 9 are electrode patterns of the same shapes as the gate electrodes 8 and 8′. The structures thereof are also the same as those of the gate electrodes 8 and 8′ apart from the absence of the gate insulating film 2. In other words, the dummy gate electrode 9 is a sort of dummy pattern which does not constitute any element (for example, an electrode, a resistance, or a capacitor) or any part of an element of a semiconductor integrated circuit. The presence or absence of the dummy pattern has no influence on the operation of the semiconductor integrated circuit. That is to say, even if the dummy pattern is absent, the semiconductor integrated circuit can operate normally. As shown in FIG. 7, the gate electrodes 8 and 8′ are connected through contact electrodes 40 and 40 to overlying interconnects 42 and 42 formed on an interlayer insulating film 44, respectively, so that the gate electrodes 8 and 8′ are electrically connected to the semiconductor integrated circuit in the semiconductor device. On the other hand, the dummy gate electrodes 9 and 9 are not electrically connected to the semiconductor integrated circuit in the semiconductor device, and they are formed in order to improve the thickness uniformity of the second silicide layers 7.

From the both sides of the gate electrode 8 at the left-hand side of FIG. 1, the gate electrode 8′ and the dummy gate electrode 9 are spaced away, respectively. Likewise, from the both sides of the gate electrode 8′ at the right-hand side of FIG. 1, the gate electrode 8 and the dummy gate electrode 9 are spaced away, respectively. This arrangement provides the second silicide layers 7 of a uniform thickness which are formed on the respective source and drain diffusion layers 5. To be more specific, since the environment during sputtering is made equal at any points of all the source and drain diffusion layers 5, the high melting point metal film is deposited to have a substantially uniform thickness on any points of the source and drain diffusion layers 5 and to have a smaller thickness than the metal film deposited on the gate electrodes 8 and 8′.

Moreover, in the first embodiment, the distance between the adjacent gate electrodes and the distance between the gate electrode and the dummy gate electrode (the distance between side walls of the respective electrodes) are standardized at a value of A, so that the second silicide layers 7 are formed to have a more uniform thickness. This thickness uniformity preferably satisfies the following relation: 2(TM−Tm)/(TM+Tm)<0.3, where TM and Tm are the maximum and minimum thicknesses of the second silicide layer 7 in the element region 10, respectively. If the value of this formula is 0.3 or more, junction leakage current caused by making a shallow junction of the source/drain diffusion layer 5 is very large and it is difficult to reduce the sheet resistance. As a result, such a value causes the degradation in the device characteristics. If the value of this formula is less than 0.2, the variation in the junction leakage current can be further small and in addition the sheet resistance can be further reduced, which is more preferable. The value of this formula less than 0.1 is ideal, which is further preferable.

On the other hand, the high melting point metal films deposited on the gate electrodes 8 and 8′ and on the dummy gate electrodes 9 and 9 are deposited to have a greater thickness than that on the source/drain diffusion layer 5. This is because unlike the case of the source/drain diffusion layer 5, there is no obstacle to deposition on both sides thereof. To be more specific, since the high melting point metal film formed by sputtering technique has poor step coverage in the formation step thereof, the high melting point metal films formed on the gate electrodes 8 and 8′ and on the dummy gate electrodes 9 and 9 have a greater thickness than that formed on the source/drain diffusion layer 5. As a result, the first silicide layer 6 is thicker than the second silicide layer 7.

As is apparent from the above, the first silicide layer 6 can be formed thicker than the second silicide layer 7, so that the possibility of the disconnection of the gate electrodes 8 and 8′ is greatly reduced. For the ratio between thicknesses of the first and second silicide layers 6 and 7, the thickness of the second silicide layer 7 is preferably 80% or less of the thickness of the first silicide layer 6. If it is 50% or less, the possibility of the disconnection of the gate electrodes 8 and 8′ is further reduced as is more preferable. However, even the second silicide layer 7 needs to have a certain thickness, so that it is not preferable that it be 20% or less.

Next description will be made of a method for fabricating a semiconductor device according to the first embodiment.

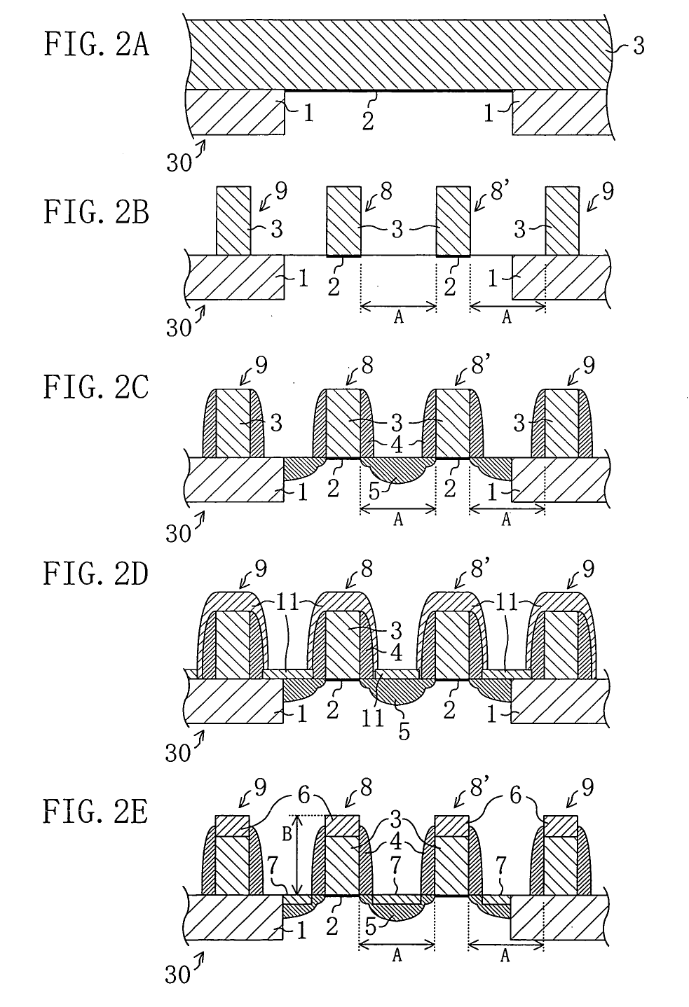

FIGS. 2A to 2E are cross-sectional views showing process steps of fabricating a semiconductor device step by step.

FIG. 2A shows the state in which the following steps are completed. The semiconductor substrate 30 is formed with the isolation insulating film 1 for electrically isolating MOS transistor elements from each other, and dopant implantation or the like for threshold voltage control is performed. The gate insulating film 2 is formed on the semiconductor substrate 30, after which the polysilicon film 3 is deposited thereon. Note that the isolation insulating film 1 has a depth of 300 nm, the gate insulating film 2 has a thickness of 2.5 nm, and the polysilicon film 3 with a thickness of 300 nm is deposited.

FIG. 2B shows the state in which the following steps are completed. On the polysilicon film 3, a gate electrode pattern is made by lithography, and then the resulting polysilicon film 3 is etched by dry etching. In these steps, the gate electrodes 8 and 8′ and the dummy gate electrodes 9 and 9 are patterned at the same time. In particular, the patterning is performed so that the distances A between the gate electrodes and between the gate electrode and the dummy gate electrode are fixed at a value of 300 nm. Note that the final heights B of the gate electrodes 8 and 8′ and of the dummy gate electrodes 9 and 9 measured after formation of the first silicide layer 6 are set to be substantially equal to the distance A between the gate electrodes (equal to the distance between the gate electrode and the dummy gate electrode).

FIG. 2C shows the state in which the following steps are completed. LDD implantation, EX implantation, pocket implantation, or other implantation is performed, and then an insulating film is deposited. The deposited film is dry etched by reactive ion etching (RIE) to form the sidewalls 4. Subsequently, dopant implantation for source and drain and activation are performed to form the source and drain diffusion layers 5. The sidewalls 4 are provided also on side walls of the dummy gate electrodes 9 and 9.

FIG. 2D shows the state in which the following steps are completed. A Cobalt (Co) film of 8 nm thickness serving as the high melting point metal film 11 is deposited using sputtering technique, and on the deposited film, a titanium nitride (TiN) film of 20 nm thickness for preventing oxidation of the Co film is deposited using sputtering technique. Since the deposition of the high melting point metal film 11 is performed by sputtering, the deposited film has poor step coverage, that is to say, the deposited films on the gate electrodes 8 and 8′ and on the dummy gate electrodes 9 and 9 are thicker than films on the source and drain diffusion layers 5 between the gate electrodes and between the gate electrode and the dummy gate electrode. In the first embodiment, when the thickness of Co deposited under the TiN film was measured, the thicknesses thereof on the gate electrodes 8 and 8′ were 8 nm, which is the target thickness. The thicknesses thereof on the source and drain diffusion layers 5 were 4 nm, which is half of the thickness on the gate electrodes 8 and 8′.

FIG. 2E shows the state in which the following steps are completed. Thermal treatment at 450° C. for 90 seconds is performed using rapid thermal anneal (RTA) technique, after which unreacted Co film and TiN film on the insulating film are removed by selective wet etching. Then, thermal treatment at 850° C. for 30 seconds is performed as a second thermal treatment. Thus, the semiconductor device of the first embodiment is fabricated. In this state, the first silicide layer 6 has a thickness of 30 nm and the second silicide layer 7 has a thickness of 15 nm, which is half of the thickness of the first silicide layer 6. The thickness uniformity of the second silicide layers 7: 2(TM−Tm)/(TM+Tm) is 0.2.

In the semiconductor device of the first embodiment, the distances A between the gate electrodes and between the gate electrode and the dummy gate electrode are set to be substantially equal to the heights B of the gate electrodes and of the dummy gate electrodes. As the distance A is smaller or the height B is greater, the second silicide layer 7 becomes still thinner than the first silicide layer 6. If the two values satisfy A≦2B, the thickness ratio between the first silicide layer 6 and the second silicide layer 7 becomes a practical value as is preferable.

Moreover, in the semiconductor device of the first embodiment, the gate length is designed at 0.1 μm, which is smaller than 0.15 μm. The semiconductor device of the first embodiment even with such a small gate length can be formed with a sufficiently thick first silicide layer 6, thereby preventing disconnection.

As is apparent from the above, in the first embodiment, the thickness difference between the first and second silicide layers 6 and 7 can be created so that the first silicide layers 6 on the gate electrodes 8 and 8′ are twice as great a thickness as the second silicide layer 7 on the source/drain diffusion layer 5. As the height B of the gate electrode is greater or the distance A between the gate electrodes (the distance between the gate electrode and the dummy gate electrode) is smaller, the thickness difference can be increased. Moreover, if the distances A are standardized in all the gate electrode regions, the silicide films on the source and drain diffusion layers 5 have a uniform thickness.

Consequently, the semiconductor device of the first embodiment makes it possible to simultaneously attain formation of thick silicide films 6 on the gate electrodes 8 and 8′ (for the purpose of reducing the sheet resistance and preventing the disconnection) and formation of a thin silicide film 7 accompanied with formation of a shallow junction of the source/drain diffusion layer 5 (for the purpose of preventing an increase in junction leakage current), both of which are demanded in accordance with the progress in miniaturization of the device.

In the first embodiment, the dummy gate electrode 9 is not electrically connected to the gate electrode 8. These electrodes may be electrically connected to each other.

### Second Embodiment

A second embodiment of the present invention will be described with reference to the accompanying drawings. The second embodiment differs from the first embodiment only in the structure of the gate electrode 8, so that different parts thereof will be described below. The structure of a semiconductor device according to the second embodiment is similar to that according to the comparative example in FIG. 6, and comparisons between these structures will also be shown.

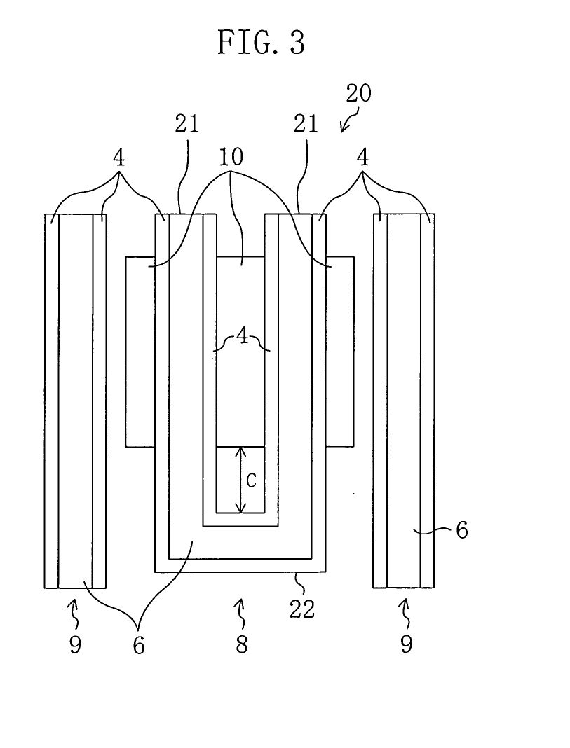

FIG. 3 is a plan view showing a semiconductor device according to the second embodiment of the present invention.

Referring to the semiconductor device exemplarily shown in FIG. 3, like the first embodiment, two parallel portions 21 and 21 of the gate electrode 8 in U-shape are formed on the element region 10 surrounded with an isolation insulating film. The dummy gate electrodes 9 and 9 are disposed on the isolation insulating film like the first embodiment. On the isolation insulating film, a connecting portion 22 is formed which connects the two parallel portions 21 and 21 of the gate electrode 8 to each other.

The second embodiment differs from the comparative example shown in FIG. 6 in that the two parallel portions 21 and 21 of the gate electrode 8 are connected not on the element region 10 but on the isolation insulating film.

The second embodiment is characterized in that the point at which the orientation of the gate electrode 8 is changed, that is, the point at which the gate electrode 8 is bent is located a distance C or longer away from the boundary between the element region 10 and the isolation insulating film. The distance C holds the relation: C≧2B relative to the gate electrode height B.

The gate electrode 8 surrounds three sides of a region. On this region, the high melting point metal film is deposited thinner than on the region only two facing sides of which adjoin the gate electrodes 8 or the gate electrode 8 and the dummy gate electrode 9. Thus, the position at which the gate electrode 8 is bent or at which the two parallel portions of the gate electrode 8 are connected is set to hold the above relation, whereby the region with the thinner film deposited thereon can be spaced from the element region 10. Consequently, the thickness of the second silicide layer 7 can be substantially uniform on any points of the element region 10.

### Third Embodiment

A third embodiment of the present invention differs from the first embodiment in that there is only one gate electrode 8, so that the different point will be described below.

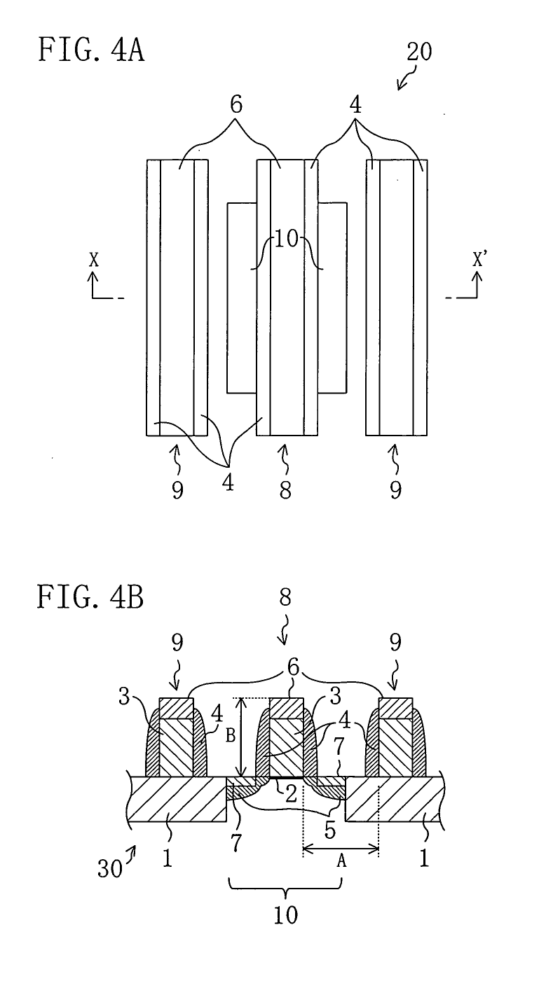

As shown in FIG. 4, in the semiconductor device of the third embodiment, one gate electrode 8 is formed on the element region 10. The dummy gate electrodes 9 and 9 are formed away from both sides of the gate electrode 8, respectively. The dummy gate electrodes 9 and 9 are formed on the isolation insulating film 1. In the third embodiment, the dummy gate electrodes 9 and 9 are formed next to the both sides of the gate electrode 8, but this structure also has the same effects as that of the first embodiment. To be more specific, by employing this structure, the second silicide layers 7 can be formed to have a uniform thickness and the first silicide layer 6 can be formed to have a sufficiently greater thickness than the second silicide layer 7.

### Fourth Embodiment

A fourth embodiment of the present invention differs from the third embodiment in that the dummy gate electrodes 9 and 9 are formed on the element region 10, so that the different point will be described below.

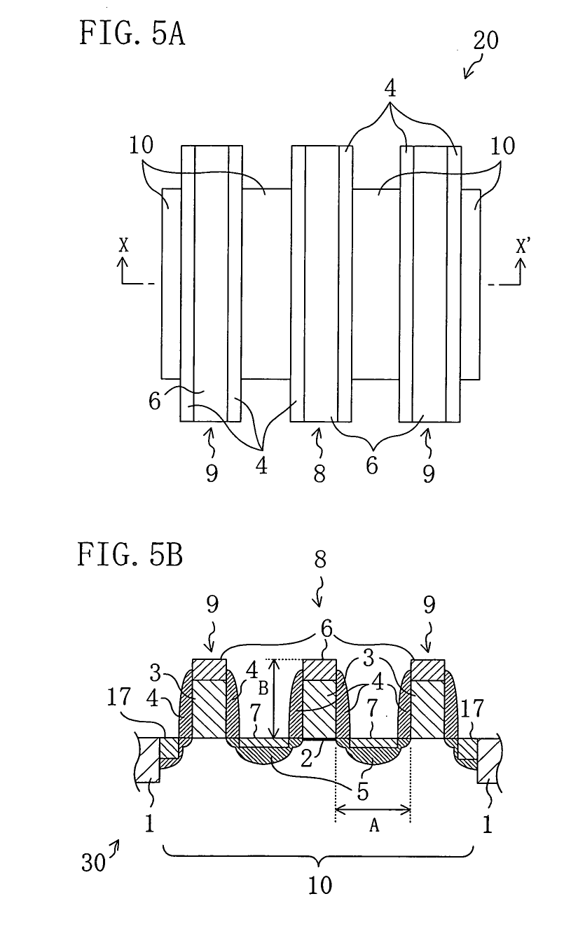

As shown in FIG. 5, in the semiconductor device of the fourth embodiment, one gate electrode 8 is formed on the element region 10. The dummy gate electrodes 9 and 9 are formed away from both sides of the gate electrode 8, respectively. The dummy gate electrodes 9 and 9 are formed also on the element region 10.

In the fourth embodiment, a silicide layer 17 is formed also in the portion of the element region 10 located between each of the dummy gate electrodes 9 and 9 and the isolation insulating film 1. The silicide layer 17 has a greater thickness than the second silicide layer 7. However, the silicide layer 17 is not involved in the operation of the MOS transistor 20. Therefore, even through the silicide layer 17 differs from the second silicide layer in thickness, no problem arises.

In the fourth embodiment, the dummy gate electrodes 9 and 9 are formed next to the both sides of the gate electrode 8, but this structure also has the same effects as that of the first embodiment. To be more specific, by employing this structure, the second silicide layers 7 can be formed to have a uniform thickness and the first silicide layer 6 can be formed to have a sufficiently greater thickness than the second silicide layer 7.

### Fifth Embodiment

A fifth embodiment of the present invention is identical to the first embodiment with the exception that a dummy pattern of insulating material is used instead of the dummy gate electrode and that a resistance element is provided. The different points will be described below.

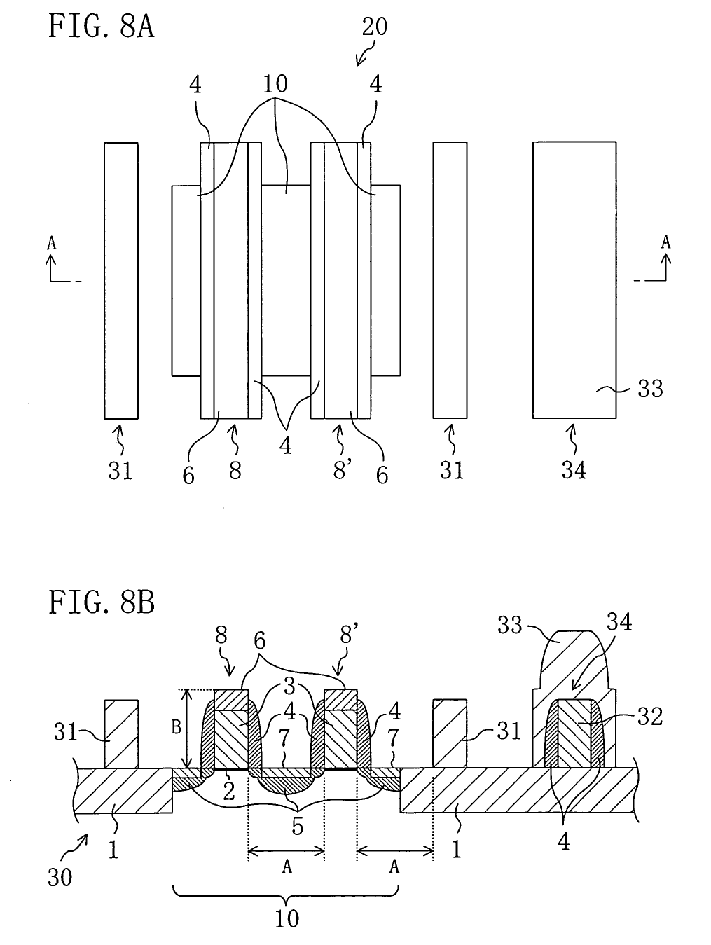

As shown in FIG. 8, in a semiconductor device of the fifth embodiment, two gate electrodes 8 and 8′ are formed in an aligned pair on the element region 10, and dummy patterns 31 and 31 are provided next to both sides of the electrode pair across the alignment direction thereof. The dummy patterns 31 and 31 are formed on the isolation insulating film 1. The distance between the gate electrode 8 and the adjacent dummy pattern 31 (or between the gate electrode 8′ and the adjacent dummy pattern 31) is equal to the distance A between the two gate electrodes 8 and 8′. The height of the dummy pattern 31 is substantially equal to the heights of the gate electrodes 8 and 8′ and almost the same as the distance between the two gate electrodes 8 and 8′. The dummy pattern 31 serves to form the second silicide layers 7 with a uniform thickness and to form the first silicide layer 6 sufficiently thicker than the second silicide layer 7, and it does not function as any elements of the semiconductor integrated circuit. On the isolation insulating film 1, a resistance element 34 is formed other than the dummy pattern 31. The resistance element 34 is composed of a resistance portion 32 of a polysilicon layer and the sidewalls 4, and an insulating material 33 is formed on the resistance element 34. The insulating material 33 is the same as the material forming the dummy patterns 31 and 31. The insulating material 33 is preferably silicon oxide, silicon nitride, or silicon oxynitride.

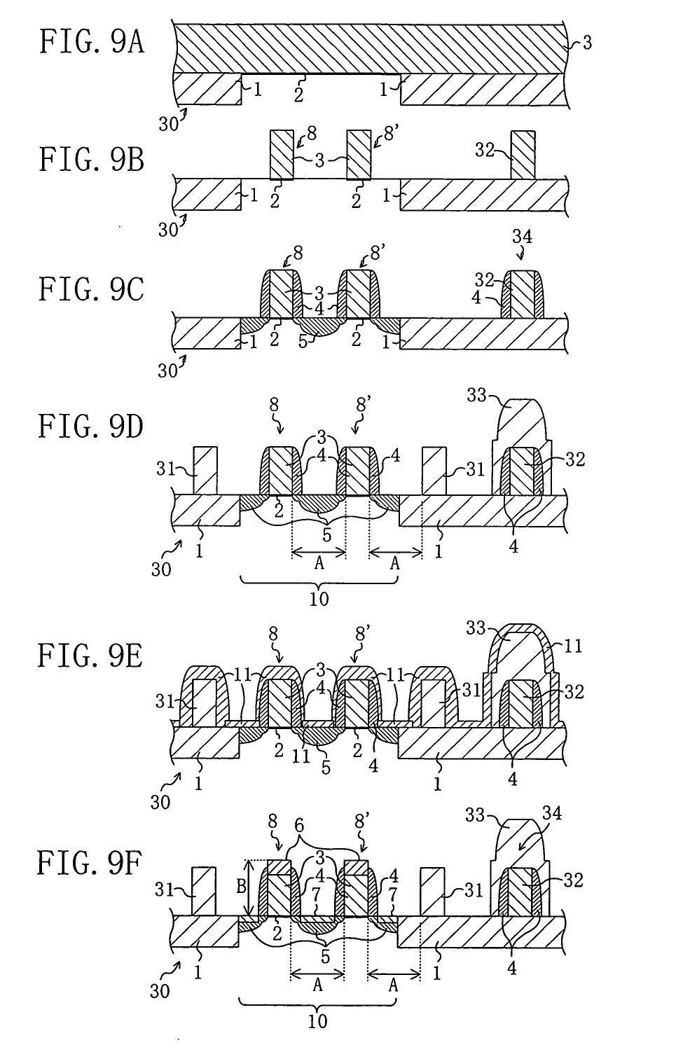

Next, a method for fabricating a semiconductor device according to the fifth embodiment will be described with reference to FIGS. 9A to 9E.

As shown in FIG. 9A, the semiconductor substrate 30 is formed with the isolation insulating film 1, the gate insulating film 2, and the polysilicon film 3. The formation step of these films is identical to that of the first embodiment.

As shown in FIG. 9B, the polysilicon film 3 is then patterned by lithography, after which the resulting polysilicon film 3 is dry etched to form the gate electrodes 8 and 8′ and the resistance portion 32 of the resistance element 34.

As shown in FIG. 9C, LDD implantation, EX implantation, pocket implantation, or other implantation is then performed, and an insulating film is deposited. The deposited film is dry etched by RIE to form the sidewalls 4. Subsequently, dopant implantation for source and drain and activation are performed to form the source/drain diffusion layers 5. The sidewalls 4 are provided also on side walls of the resistance portion 32.

As shown in FIG. 9D, using CVD technique or sputtering technique, an insulating layer is formed on the entire surface above the semiconductor substrate 30. The formed insulating layer is patterned and etched to form the dummy patterns 31 and 31 made of insulating material. During the dummy pattern formation step, the insulating material 33 is formed also on the resistance portion 32 and on the sidewalls 4 in contact with the resistance portion 32.

As shown in FIG. 9E, a Co film serving as the high melting point metal film 11 is formed on the entire surface above the semiconductor substrate 30. The formation method and the thickness of the Co film are the same as those of the first embodiment.

As shown in FIG. 9F, the first and second silicide layers 6 and 7 are formed using the same method as the first embodiment. Note that silicide is produced in an area where a silicon layer is in contact with a Co film and not produced in an area where an insulating layer is in contact with the Co film. The thickness and the uniformity of the formed silicide are the same as those of the first embodiment.

Also in the fifth embodiment, the semiconductor device makes it possible to simultaneously attain formation of thick silicide films 6 on the gate electrodes 8 and 8′ (for the purpose of reducing the sheet resistance and preventing the disconnection) and formation of a thin silicide film 7 accompanied with formation of a shallow junction of the source/drain diffusion layer 5 (for the purpose of preventing an increase in junction leakage current), both of which are demanded in accordance with the progress in miniaturization of the device.

### Sixth Embodiment

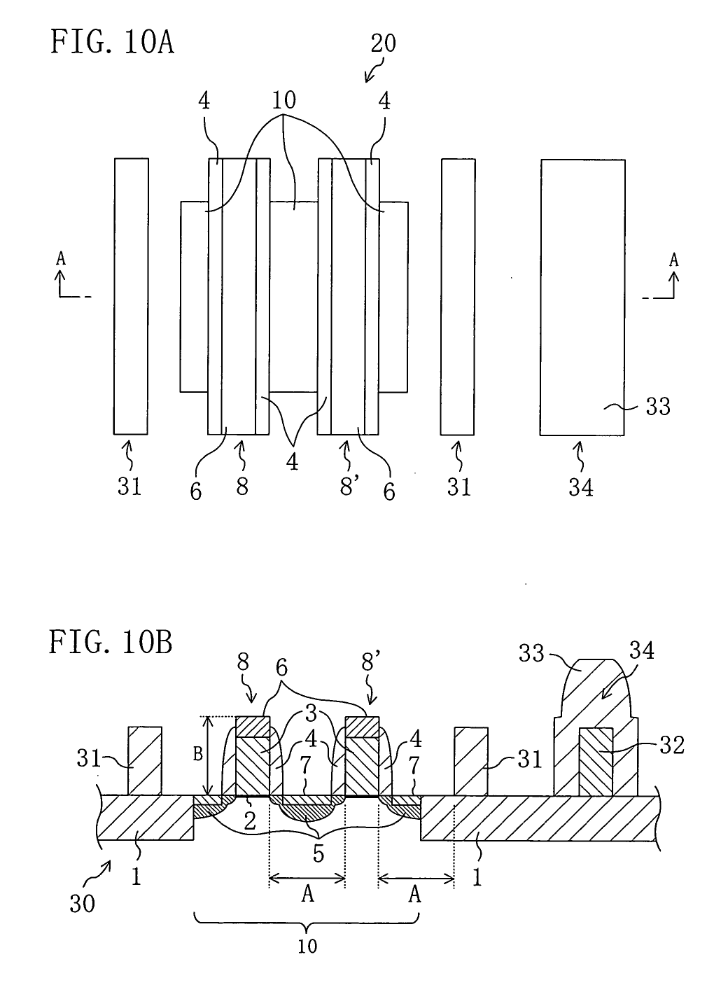

A semiconductor device according to a sixth embodiment of the present invention is identical in a plan view to that of the fifth embodiment, as shown in FIG. 10A. However, a fabrication method thereof differs from that of the fifth embodiment, so that the fabrication method will be described below.

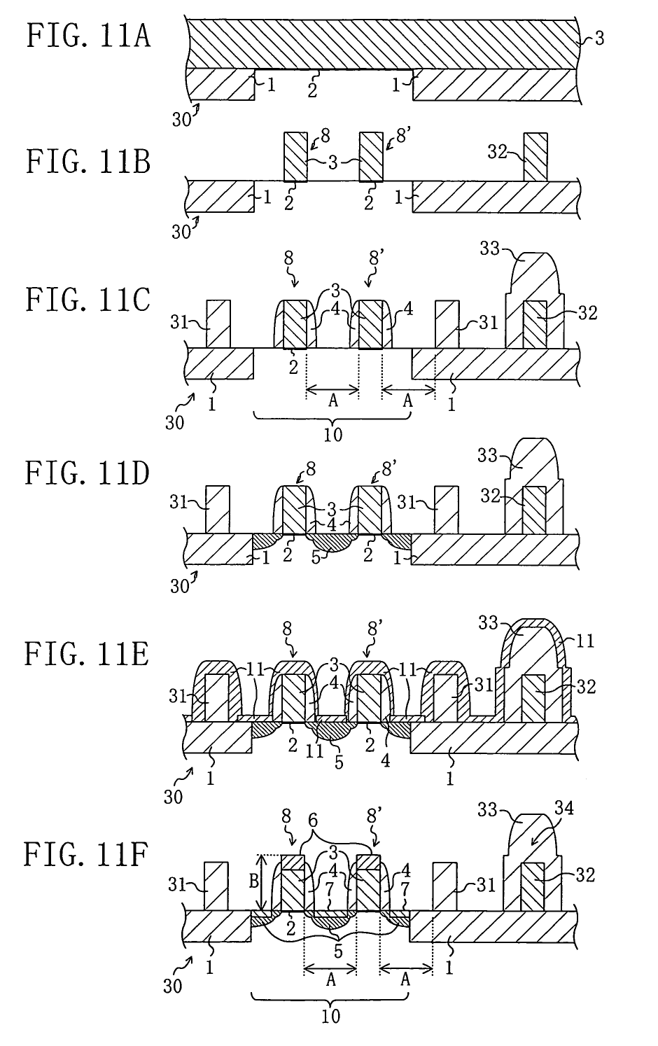

First, as shown in FIG. 11A, the semiconductor substrate 30 is formed with the isolation insulating film 1, the gate insulating film 2, and the polysilicon film 3. The formation step of these films is identical to that of the fifth embodiment.

As shown in FIG. 11B, the polysilicon film 3 is then patterned by lithography, after which the resulting polysilicon film 3 is dry etched to form the gate electrodes 8 and 8′ and the resistance portion 32 of the resistance element 34. The formation step of these is identical to that of the fifth embodiment.

Next, as shown in FIG. 11C, using CVD technique or sputtering technique, an insulating layer is formed on the entire surface above the semiconductor substrate 30. The formed insulating layer is patterned and etched to form the dummy patterns 31 and 31 made of insulating material. This formation step differs from that of the fifth embodiment. During the dummy pattern formation step, the insulating material 33 is formed also on the resistance portion 32. At the same time, the sidewalls 4 are formed on both sides of the respective polysilicon films 3 and 3 which will constitute the gate electrodes 8 and 8′. Unlike the fifth embodiment, no sidewall is formed on both sides of the resistance portion 32 in the sixth embodiment.

As shown in FIG. 11, LDD implantation, EX implantation, pocket implantation, or other implantation is then performed, after which dopant implantation for source and drain and activation are performed to form the source and drain diffusion layers 5. Unlike the fifth embodiment, this step is performed after the sidewall formation step.

As shown in FIG. 11E, a Co film serving as the high melting point metal film 11 is formed on the entire surface above the semiconductor substrate 30. The formation method and the thickness of the Co film are the same as those of the first embodiment.

As shown in FIG. 11F, the first and second silicide layers 6 and 7 are formed using the same method as the first embodiment. The thickness and the uniformity of the formed silicide are the same as those of the first embodiment.

Also in the sixth embodiment, the semiconductor device makes it possible to simultaneously attain formation of thick silicide films 6 on the gate electrodes 8 and 8′ (for the purpose of reducing the sheet resistance and preventing the disconnection) and formation of a thin silicide film 7 accompanied with formation of a shallow junction of the source/drain diffusion layer 5 (for the purpose of preventing an increase in junction leakage current), both of which are demanded in accordance with the progress in miniaturization of the device.

### Seventh Embodiment

A semiconductor device according to a seventh embodiment of the present invention has a structure in which two gate electrodes are aligned in pair and one dummy gate electrode and one dummy pattern are spaced away from both sides of the electrode pair across the alignment direction of the electrodes, respectively. That is to say, the seventh embodiment can be considered to be a combination of the first and fifth embodiments.

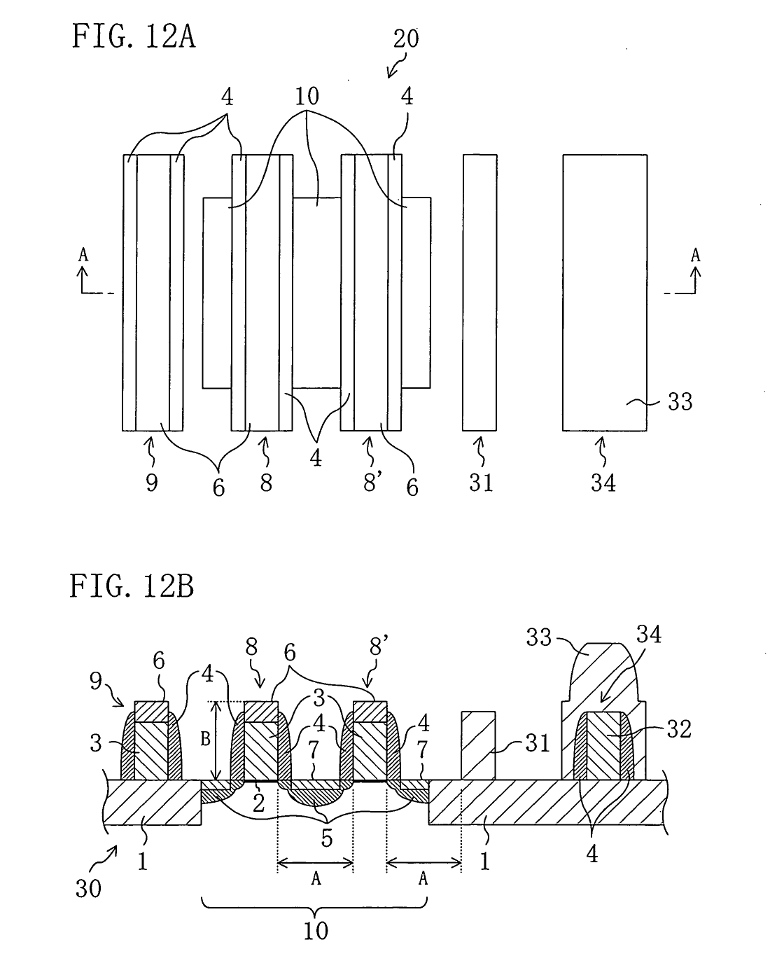

In the semiconductor device according to the seventh embodiment, as shown in FIG. 12, the dummy gate electrode 9, the gate electrodes 8 and 8′, the dummy pattern 31, and the resistance element 34 are arranged in the listed order from left to right. The distances between the dummy gate electrode 9 and the gate electrode 8 and between the gate electrode 8′ and the dummy pattern 31 are substantially equal to the distance A between the two gate electrodes 8 and 8′. The dummy pattern 31 is made of insulating material and the dummy gate electrode 9 is not electrically connected to any elements of the semiconductor integrated circuit. The dummy gate electrode 9 and the dummy pattern 31 are formed on the isolation insulating film 1, and the heights of them are substantially equal to the heights B of the gate electrodes 8 and 8′.

Also in the seventh embodiment, the semiconductor device makes it possible to simultaneously attain formation of thick silicide films 6 on the gate electrodes 8 and 8′ (for the purpose of reducing the sheet resistance and preventing the disconnection) and formation of a thin silicide film 7 accompanied with formation of a shallow junction of the source/drain diffusion layer 5 (for the purpose of preventing an increase in junction leakage current), both of which are demanded in accordance with the progress in miniaturization of the device.

A fabrication method of a semiconductor device according to the seventh embodiment is a combination of the fabrication methods of the first and fifth embodiments, so that its description is omitted. Note that the fabrication method of the sixth embodiment may be employed instead of the fabrication method of the fifth embodiment. In this case, however, the structure of the resistance element 34 slightly varies.

In each embodiment described above, cobalt (Co) is used as high melting point metal and cobalt silicide (CoSi₂) is used as silicide. Alternatively, titanium (Ti) may be used as high melting point metal and titanium silicide (TiSi₂) may be used as silicide. Also, nickel (Ni) may be used as high melting point metal and nickel silicide (NiSi₂) may be used as silicide. Further, platinum (Pt) may be used as high melting point metal and platinum silicide (PtSi₂) may be used as silicide. The metal and Si contents of each silicide vary according to the temperature of the heat treatment. Where silicide is represented by CoSiₓ, TiSiₓ, NiSiₓ, or PtSiₓ, if x satisfies 0<x≦2, the resistance can be reduced to a small value.

In forming the gate electrode, an amorphous silicon film may be used instead of the polysilicon film.

The seventh embodiment is a combination of the first and fifth embodiments. Alternatively, the seventh embodiment may be a combination of the second, third or fourth embodiment and the fifth or sixth embodiment.

By employing the semiconductor device and the fabrication method thereof according to the present invention, the silicide films on the source and drain diffusion layers can have a substantially uniform thickness, and simultaneously the difference in thickness can be created between the silicide film on the gate electrode and the silicide film on the source/drain diffusion layer. As the height B of the gate electrode is greater or the distance A between the gate electrodes (the distance between the gate electrode and the dummy pattern) is smaller, it is possible to increase the thickness difference between the silicide film on the gate electrode and the silicide film on the source/drain diffusion layer.

Consequently, the semiconductor device of the present invention makes it possible to simultaneously attain formation of a thick silicide film on the gate electrode (for the purpose of reducing the sheet resistance and preventing the disconnection) and formation of a thin silicide film accompanied with formation of a shallow junction of the source/drain diffusion layer (for the purpose of preventing an increase in junction leakage current), both of which are demanded in accordance with the progress in miniaturization of the device.

What is claimed is:

1. A semiconductor device comprising a MOS transistor with a gate electrode,
wherein a dummy pattern is spaced away from both sides of the gate electrode,
a first silicide layer is formed in the upper portion of the gate electrode,
a second silicide layer is formed in a region between the gate electrode and the dummy pattern, and
the first silicide layer has a greater thickness than the second silicide layer.

2. A semiconductor device comprising a MOS transistor with a plurality of gate electrodes,
wherein each of the gate electrodes is arranged between the other gate electrodes or between one of the gate electrodes and a dummy pattern with a space left at each side thereof,
a first silicide layer is formed in the upper portion of the gate electrode,
a second silicide layer is formed in a region between the gate electrode and at least one of another gate electrode and the dummy pattern, and
the first silicide layer has a greater thickness than the second silicide layer.

3. The device of claim 1 or 2, wherein the dummy pattern is a dummy gate electrode which is an electrode pattern having the shape of a gate electrode, and the dummy pattern is an electrode which is not electrically connected to a semiconductor integrated circuit of the semiconductor device.

4. The device of claim 1 or 2, wherein the dummy pattern is made of insulating material.

5. The device of claim 1 or 2, wherein the dummy pattern is either a pattern made of insulating material or a dummy gate electrode which is an electrode pattern having the shape of a gate electrode and is not electrically connected to a semiconductor integrated circuit of the semiconductor device.

6. The device of claim 4, wherein the MOS transistor is formed in an element region surround with an isolation insulating film, and
the pattern made of insulating material is formed on the isolation insulating film.

7. The device of claim 5, wherein the MOS transistor is formed in an element region surround with an isolation insulating film, and
the pattern made of insulating material is formed on the isolation insulating film.

8. The device of claim 1 or 2, wherein the thickness of the second silicide layer is 80% or less of the thickness of the first silicide layer.

9. The device of claim 1 or 2, wherein the MOS transistor is formed in an element region surrounded with an isolation insulating film, and
the thickness of the second silicide layer or layers satisfies 2(TM−Tm)/(TM+Tm)<0.3, where TM and Tm are the maximum and minimum thicknesses of the second silicide layer or layers in the element region, respectively.

10. The device of claim 1 or 2, wherein the distance A from a side wall of the gate electrode to a side wall of another said gate electrode or a side wall of the dummy pattern adjacent to the gate electrode holds the relation: A≦2B relative to the height B of the gate electrode.

11. The device of claim 10, wherein the MOS transistor is formed in an element region surrounded with an isolation insulating film,
the gate electrode comprises two portions extending substantially parallel to each other and a connecting portion connecting respective ends of the two portions to each other,
the connecting portion is located on the isolation insulating film, and
the distance C from the boundary between the isolation insulating film and the element region to the connecting portion holds the relation: C≧2B relative to the gate electrode height B.

12. The device of claim 1 or 2, wherein the MOS transistor has a gate length of 0.15 μm or smaller.

13. The device of claim 1 or 2, wherein the first and second silicide layers contain one selected from the group consisting of CoSiₓ, TiSiₓ, NiSiₓ, and PtSiₓ , and x satisfies 0<x≦2.

14. A semiconductor device comprising a MOS transistor with a plurality of gate electrodes,
wherein the gate electrodes are formed on a semiconductor substrate having a silicon layer at least in the surface thereof,
the MOS transistor has a gate length of 0.15 μm or smaller and is formed in an element region surrounded with an isolation insulating film,
each of the gate electrodes is arranged between the other gate electrodes or between one of the other electrodes and a dummy pattern with a space left from each side thereof,
sidewalls are provided on side walls of each of the gate electrodes and on side walls of another said gate electrode,
a first silicide layer is formed in the upper portion of the gate electrode,
a second silicide layer is formed in a portion of the semiconductor substrate surface which is located in part of the element region between the gate electrode and at least one of another gate electrode and the dummy pattern, and
the first silicide layer has a greater thickness than the second silicide layer.

15. The device of claim 14, wherein the dummy pattern is a dummy gate electrode which is an electrode pattern having the shape of a gate electrode, side walls of the dummy pattern are provided with sidewalls, and the dummy pattern is an electrode which is not electrically connected to a semiconductor integrated circuit of the semiconductor device.

16. The device of claim 14, wherein the dummy pattern is made of insulating material.

17. The device of claim 14, wherein the dummy pattern is either a pattern made of insulating material or a dummy gate electrode which is an electrode pattern having the shape of a gate electrode with side walls of the dummy pattern provided with sidewalls and is not electrically connected to a semiconductor integrated circuit of the semiconductor device.

18. The device of claim 16 or 17, wherein the pattern made of insulating material is formed on the isolation insulating film.

19. A method for fabricating a semiconductor device, comprising the steps of:
forming a gate insulating film on a semiconductor substrate having a silicon layer at least in the surface thereof, and depositing an amorphous silicon film or a polysilicon film on the gate insulating film;
patterning the amorphous silicon film or the polysilicon film to form a gate electrode and at least one of another gate electrode and a dummy gate electrode, at least one said electrode being spaced away from both sides of the gate electrode;
doping impurities into the semiconductor substrate to form doped layers serving as a source and a drain; and
depositing a metal film on the semiconductor substrate, the gate electrode, and another said gate electrode or the dummy gate electrode, and performing heat treatment on the metal film, thereby forming silicide on the semiconductor substrate, the gate electrode, and at least one electrode of another said gate electrode and the dummy gate electrode.

20. The method of claim 19, further comprising the step of forming sidewalls on side walls of the gate electrode and on side walls of at least one electrode of another said gate electrode and the dummy gate electrode.

21. A method for fabricating a semiconductor device, comprising the steps of:
forming a gate insulating film on a semiconductor substrate having a silicon layer at least in the surface thereof, and depositing an amorphous silicon film or a polysilicon film on the gate insulating film;
patterning the amorphous silicon film or the polysilicon film to form a plurality of aligned gate electrodes in array form;
doping impurities into the semiconductor substrate to form doped layers serving as a source and a drain;
depositing an insulating layer on the semiconductor substrate;
patterning the insulating layer to form dummy patterns disposed away from both sides of the electrode array in the alignment direction thereof, respectively; and
depositing a metal film on the semiconductor substrate, the gate electrode, and the dummy patterns, and performing heat treatment on the metal film, thereby forming silicide on the semiconductor substrate and the gate electrode.

22. A method for fabricating a semiconductor device, comprising the steps of:
forming an isolation insulating film on a semiconductor substrate having a silicon layer at least in the surface thereof, to form an element region surrounded with the isolation insulating film;
forming a gate insulating film on the semiconductor substrate, and depositing an amorphous silicon film or a polysilicon film on the gate insulating film;
patterning the amorphous silicon film or the polysilicon film to form a gate electrode on the element region and form a dummy gate electrode disposed on the isolation insulating film and adjacent to the gate electrode;
doping impurities into the semiconductor substrate to form doped layers serving as a source and a drain;
depositing an insulating layer on the semiconductor substrate;
patterning the insulating layer to form a dummy pattern disposed on the isolation insulating film and adjacent to the gate electrode; and
depositing a metal film on the semiconductor substrate, the gate electrode, the dummy gate electrode, and the dummy pattern, and performing heat treatment on the metal film, thereby forming silicide on the semiconductor substrate, the gate electrode, and the dummy gate electrode.

23. The method of claim 22, further comprising the step of forming sidewalls on side walls of the gate electrode and on side walls of the dummy gate electrode.

24. The method of claim 19 through 23, wherein the metal film contains one selected from the group consisting of Co, Ti, Ni, and Pt.
